(19) United States
(12) Patent Application Publication
(10) Pub. No.: US 2014/0073114 A1
(43) Pub. Date: Mar. 13, 2014

(54) IN-SITU ACTIVE WAFER CHARGE SCREENING BY CONFORMAL GROUNDING

(71) Applicants: GlobalFoundries Inc., Milpitas, CA (US); International Business Machines Corporation, Armonk, NY (US)

(72) Inventors: Cheng Cen, Morgantown, WV (US); Steven B. Herschbein, Hopewell Junction, NY (US); Narender Rana, Highland, NY (US); Nedal R. Saleh, Santa Clara, CA (US); Alok Vaid, Ballston Lake, NY (US)

(73) Assignees: GlobalFoundries Inc., Milpitas, CA (US); International Business Machines Corporation, Armonk, NY (US)

(21) Appl. No.: 14/077,517

(22) Filed: Nov. 12, 2013

Related U.S. Application Data
(62) Division of application No. 13/368,630, filed on Feb. 8, 2012.

(51) Int. Cl. H01L 21/326

(52) U.S. Cl. CPC H01L 21/326
USPC 438/466

(57) ABSTRACT

Embodiments of the invention relate generally to semiconductor wafer technology and, more particularly, to the use of conformal grounding for active charge screening on wafers during wafer processing and metrology. A first aspect of the invention provides a method of reducing an accumulated surface charge on a semiconductor wafer, the method comprising: grounding a layer of conductive material adjacent a substrate of the wafer; and allowing a mirrored charge substantially equal in magnitude and opposite in sign to the accumulated surface charge to be induced along the conductive material.

### CROSS-REFERENCE TO RELATED APPLICATIONS

This application is a divisional of currently pending U.S. patent application Ser. No. 13/368,630 filed on 8 Feb. 2012. The application identified above is incorporated herein by reference in its entirety for all that it contains in order to provide continuity of disclosure.

### BACKGROUND

Embodiments of the invention relate generally to semiconductor wafer technology and, more particularly, to the use of conformal grounding for active charge screening on wafers during wafer processing and metrology.

Wafer charging during manufacture and measurement is a major challenge that can have dramatic impacts on manufacturing yields. Charge build-up on and in wafers during manufacture and measurement is attributable to their non-conductive materials, including silicon, common resist materials, dielectric materials, and low-k materials. Surface charge and bulk charge can produce electrical potentials peaking at several hundred volts, especially around sharp and high aspect ratio features. Silicon-on-insulator (SOI) wafers tend to suffer from greater charging than bulk silicon wafers due to the presence of oxide insulation.

Wafers can accumulate and retain charge for a variety of reasons, some of which are unavoidable in wafer processing and metrology. Simple handling of wafers, including their loading onto and unloading from various machines can result in charge accumulation. Other processing and metrology techniques necessarily employ electrical current, which can result in wafer charging. For example, high-current ion implanters deliver around 25 mA, e-beam lithography tools deliver about 10 μA, and critical dimension scanning electron microscopes (CDSEMs) deliver around 10 pA to a wafer. Other charging sources include ultra-violet (UV) and X-ray irradiation.

The effects of wafer charging are varied and significant. For example, e-beam-based metrology techniques can cause registration, alignment, and automation failure, as well as distortion in e-beam-based image formation. Plasma processing technologies and ultra-low energy implanters can cause process excursion. Poor device performance can result from electrical discharge or permanent trapping around a device or memory area. Imaging using low landing-energy e-beams is more susceptible to wafer surface charging, resulting in the need to reduce the landing voltage of CDSEM beams to limit resist shrinkage. Photomasks and atomic force microscopy (AFM) also result in substrate and wafer charging.

Known attempts to address wafer charging suffer from at least two drawbacks. First, they are typically voltage-based, rather than charge-based. That is, known attempts apply a voltage to the wafer, which is premised on two assumptions, neither of which is generally true. The first assumption is that the wafer capacitance is constant. The second assumption is that the trapped charge is static.

A second drawback of known attempts to address wafer charging is that they are tool-based. This necessarily adds to the cost of manufacture and metrology and shifts the solution from the manufacturing facility to the tool vendor side of the business.

For example, surface-charge potential measurement (SPM) uses a set of electrostatic probes in the wafer transfer path to map an electric potential attributable to trapped charges. A corrective voltage corresponding to the mapped potential is superimposed on the wafer locally. This technique necessarily only corrects for charges accumulated before wafer loading and does not correct or otherwise address wafer charge accumulation during processing or loading, and does not account for charge diffusion in the wafer bulk after loading into the tool chamber.

Other attempts to correct wafer charging have used electron showers or floods following some implant operations. However, this only neutralizes positive charges and runs the very real risk of negatively over charging the wafer.

Still other attempts involve washing wafers with deionized water or carbon dioxide. Aside from the high cost, such techniques necessarily only neutralize surface charges and have no effect on charges trapped in the wafer bulk.

### SUMMARY

The invention provides a method of reducing an accumulated charge in a semiconductor wafer and a wafer structure therefor.

A first aspect of the invention provides a method of reducing an accumulated surface charge on a semiconductor wafer, the method comprising: grounding a layer of conductive material adjacent a substrate of the wafer; and allowing a mirrored charge substantially equal in magnitude and opposite in sign to the accumulated surface charge to be induced along the conductive material.

A second aspect of the invention provides a method of reducing an accumulated bulk charge in a semiconductor wafer, the method comprising: grounding a layer of conductive material adjacent a substrate of the wafer; and allowing a mirrored charge substantially equal in magnitude and opposite in sign to the accumulated bulk charge to be induced along the conductive material.

A third aspect of the invention provides a semiconductor wafer comprising: a substrate including a semiconductor material; and a layer of conductive material, wherein the layer of conductive material, when connected to a ground, is capable of developing an induced charge opposite in sign to an accumulated charge along a surface of the substrate or within the substrate.

The illustrative aspects of the present invention are designed to solve the problems herein described and other problems not discussed which are discoverable by a skilled artisan.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIGS. 1 and 2 show, respectively, a cross-sectional side view and a top view of an accumulated charge on a semiconductor wafer.

FIGS. 3A and 3B show, respectively, critical dimension scanning electron microscope (CDSEM) images of a charged and an uncharged semiconductor wafer.

FIG. 4 shows a cross-sectional side view of a semiconductor wafer according to an embodiment of the invention.

FIGS. 5 and 6 show top views of, respectively, an accumulated charge and an induced charge on the semiconductor wafer of FIG. 4.

FIG. 7 shows a cross-sectional side view of a semiconductor wafer according to another embodiment of the invention.

FIG. 8 shows a cross-sectional side view of a semiconductor wafer according to another embodiment of the invention.

FIG. 9 shows a cross-sectional side view of a semiconductor wafer according to another embodiment of the invention.

FIG. 10 shows a cross-sectional side view of a semiconductor wafer according to another embodiment of the invention.

FIGS. 11A-G show graphical representations of electron beam ray traces at various degrees of wafer charging.

FIGS. 12A-G show graphical representations of electron beam resolutions at various degrees of wafer charging.

FIGS. 13A-E show CDSEM images at various degrees of wafer charging.

FIG. 14 shows a graph of electron beam radius as a function of wafer charging in semiconductor wafers with and without a grounded back coat.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

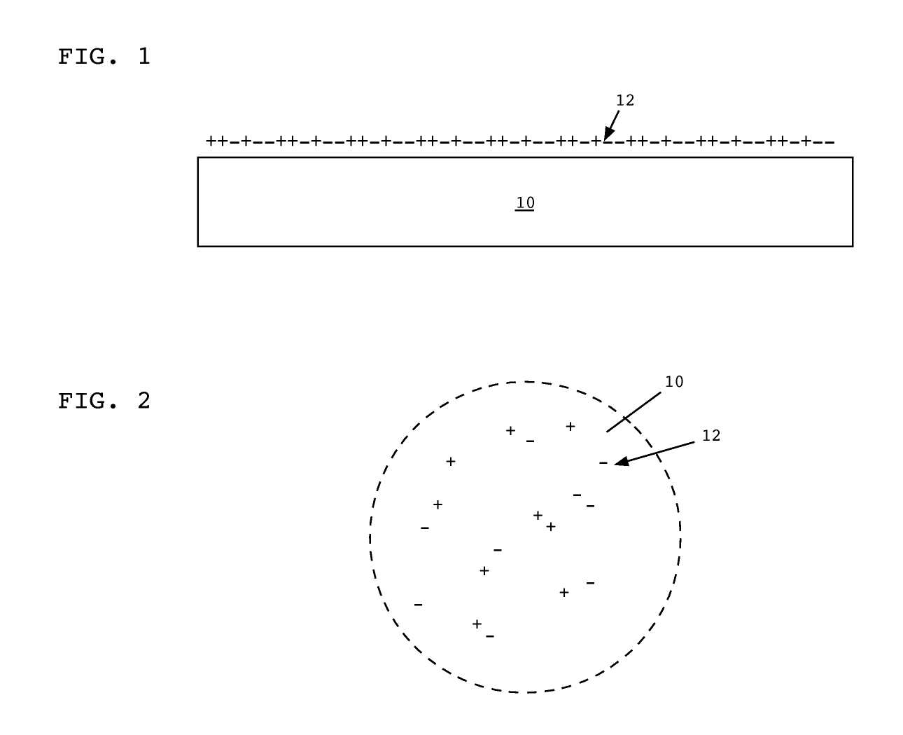

Turning now to the drawings, FIG. 1 shows a cross-sectional side view of a semiconductor wafer 10. An accumulated charge 12 is present along a surface of semiconductor wafer 10, as may be induced, for example, by wafer handling or the use of processing and/or metrology instruments, such as those described above. Although not shown in FIG. 1, but will be described in greater detail below, an accumulated charge may be present in the bulk of semiconductor wafer 10 rather than or in addition to along a surface of semiconductor wafer 10. FIG. 2 shows a top view of a distribution of accumulated charge 12 along the surface of semiconductor wafer 10.

Semiconductor wafer 10 may include any number of semiconducting materials, including, for example, silicon, germanium, silicon germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). Furthermore, a portion or entire semiconductor substrate may be strained.

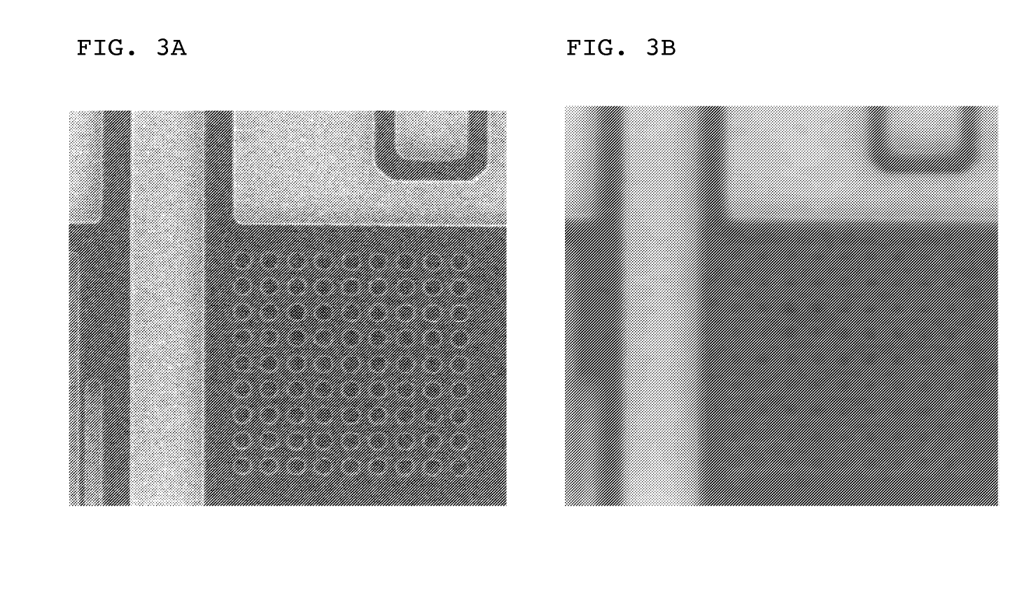

FIGS. 3A and 3B show, respectively, critical dimension scanning electron microscope (CDSEM) images of an uncharged semiconductor wafer and a charged semiconductor wafer. As can be seen in FIG. 3B, wafer charging has resulted in image defocusing, making measurement of wafer features less accurate than is possible with the uncharged wafer in FIG. 3A. As wafer charging and image defocusing increase, measurement necessarily becomes less accurate and, eventually, impossible. Other metrology problems are associated with wafer charging, including, for example, beam drift and distortion.

FIG. 4 shows a cross-sectional side view of semiconductor wafer 10 according to one embodiment of the invention. Here, a back coat 20 of conductive material is disposed along a surface of semiconductor wafer 10 opposite accumulated charge 12. Back coat 20 may include any conductive material or combination of conductive materials, including metals. Suitable conductive materials include, for example, copper, silver, aluminum, gold, tungsten, zinc, nickel, lithium, iron, platinum, tin, lead, titanium, graphite, carbon nanotubes, and carbon nanowires. Similarly, back coat 20 may be applied to semiconductor wafer 10 using any suitable technique, including, for example, chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

Once connected to a ground 30, back coat 20 develops an induced charge 22 equal in magnitude but opposite in sign to the accumulated charge 12. Thus, induced charge 22 may be referred to as a mirrored charge, i.e., a charge that is equal to and opposite accumulated charge 12. This technique, known in electrodynamics as “the method of images,” makes no assumptions as to the charge profile or distribution in accumulated charge 12.

Once grounded, the charge is mirrored dynamically in real time. The resulting dipole configuration causes an order of magnitude reduction in the collective field above the wafer and is independent of the original wafer charge profile, polarity or magnitude.

In essence, semiconductor wafer 10 and grounded back coat 20 forms an effective dipole moment, reducing the interaction between semiconductor wafer 10 and processing plasma or a charged beam being applied to semiconductor wafer. This significantly mitigates distortion in primary electron beam optics and secondary emission beam collection for electron beam imaging and reduces etch and implant irregularities in wafer processing.

By way of illustration and with the assumption for simplicity that the accumulated charge density on the wafer is constant, then the electric potential caused by induced charge 22 may be calculated according to Equation 1 below, wherein I is the electric potential caused by induced charge 22, z is a distance from a surface of the semiconductor wafer, d is a thickness of the semiconductor wafer, and D is a diameter of the semiconductor wafer.

$$I = - \frac{σ}{2 ɛ ( \sqrt{{( z + 2 d )}^{2} + {D}^{2}} - z - 2 d )} \qquad Equation 1$$

Electric potential caused by accumulated charge 12 may be calculated according to Equation 2 below, wherein A is the electric potential caused by accumulated charge, a is a surface charge density and c is a permittivity constant.

$$A = \frac{σ}{2 ɛ ( \sqrt{{z}^{2} + {D}^{2}} - z )} \qquad Equation 2$$

Thus, induced charge 22 results in a reduction in the total potential above the semiconductor wafer 10 of approximately an order of magnitude. The total potential (Vₜₒₜₐₗ) above the semiconductor wafer 10 may be calculated according to Equation 3 below.

$${V}_{total} = ( \frac{σ}{2 ɛ} \sqrt{{z}^{2} + {D}^{2}} - z ) - \sqrt{{( z + 2 d )}^{2 } + {D}^{2}} - z - 2 d \frac{σ}{2 ɛ [ ( \sqrt{{z}^{2} + {D}^{2}} - z ) - ( \sqrt{{( z + 2 d )}^{2} + {D}^{2}} - z - 2 d ) ]} \qquad Equation 3$$

Any other similar approach to calculate the total potential above the wafer, analytical or numerical, with generalization of the accumulated charge profile is also implied in this invention without any loss of generality.

Back coat 20 should preferably be as thin as possible without adversely affecting its ability to develop induced charge 22. The thickness of back coat 20 will therefore vary, depending on the conductive material(s) included in back coat 20, as well as the method(s) or technique(s) by which back coat 20 is applied. Typical thicknesses of back coat 20 may range from between about a few (e.g., three) nanometers and about a few (e.g., three) microns. One skilled in the art will recognize, however, that this range is merely illustrative of thicknesses typical of some embodiments of the invention and is not meant to be limiting of the scope of the invention. A back coat 20 of any conductive material of any thickness that is capable of developing induced charge 22 is within the scope of the invention.

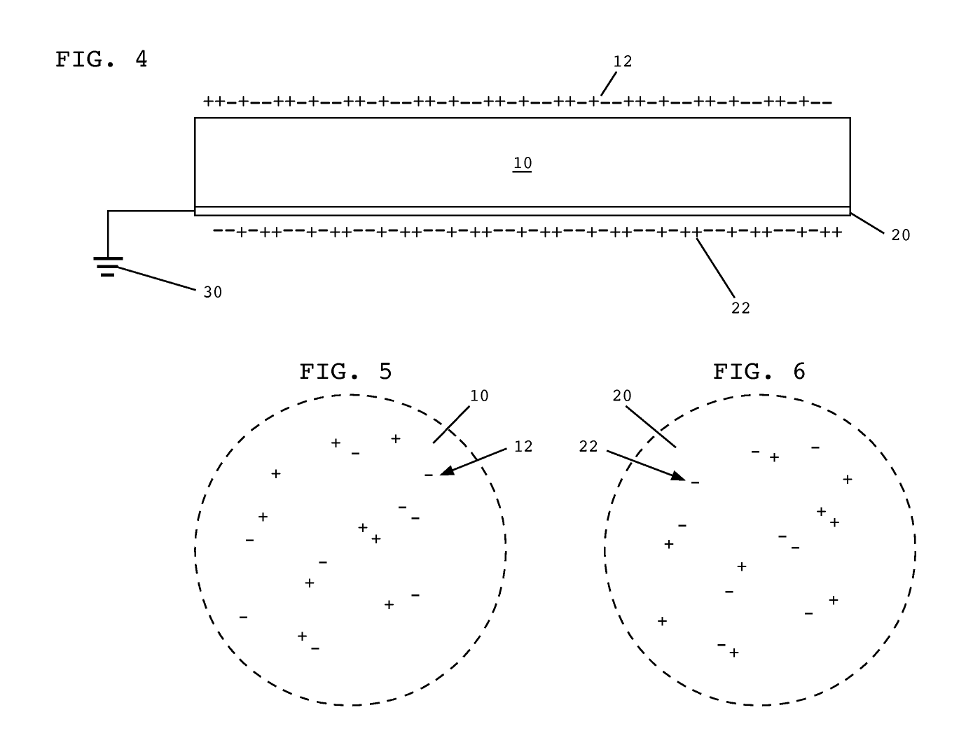

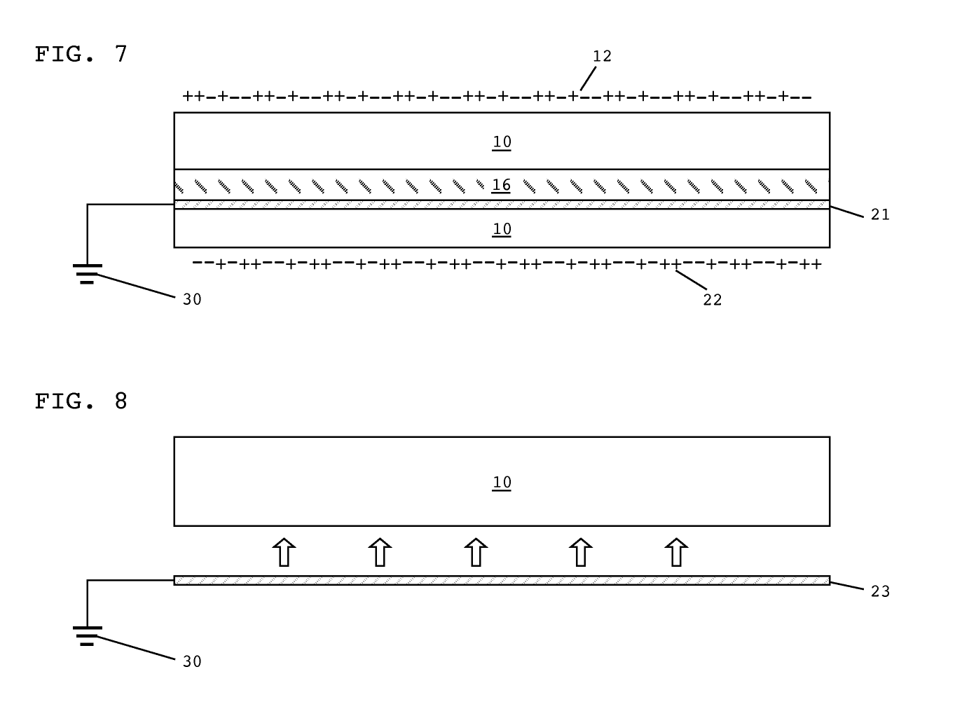

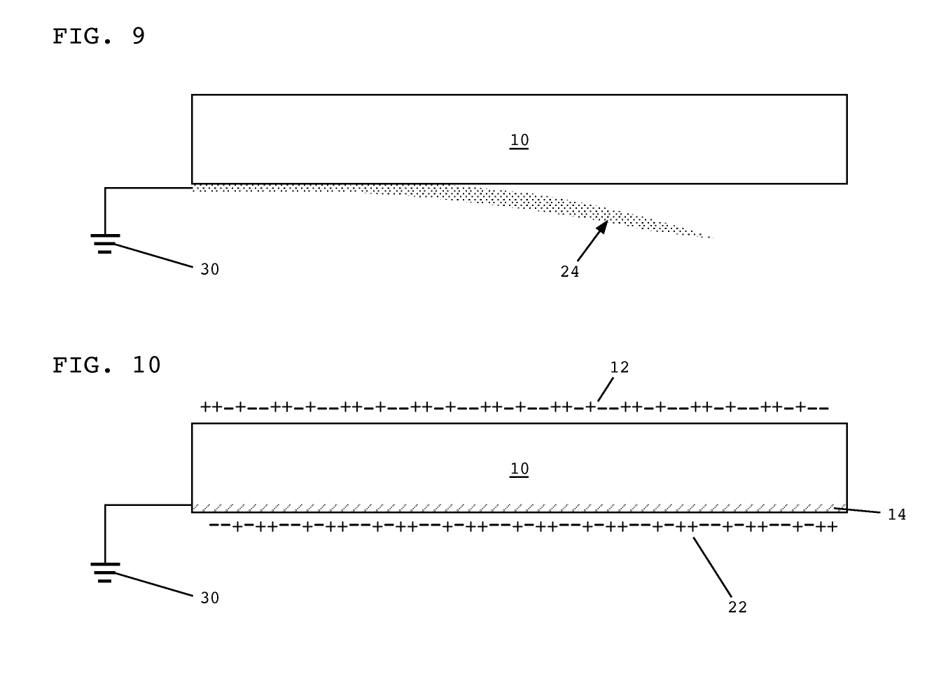

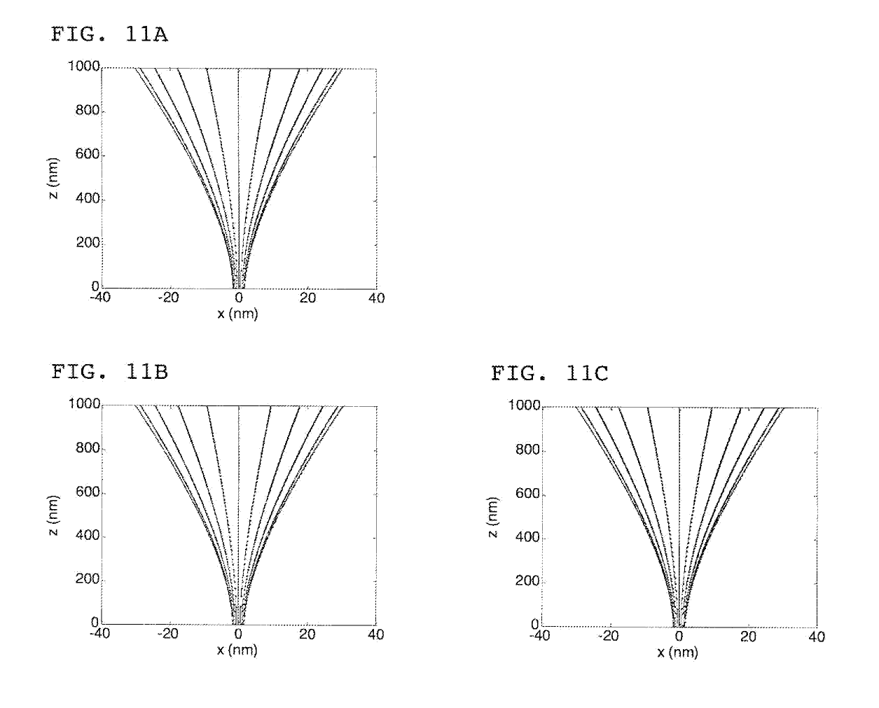

FIGS. 5 and 6 show, respectively, top views of a distribution of accumulated charge 12 on semiconductor wafer 10 (as in FIG. 2) and a distribution of induced charge 22 along back coat 20. As can be seen in FIGS. 4-6, induced charge 22 includes charges opposite in sign to accumulated charge 12.

It should be noted that ground 30 may be a non-zero potential. That is, a total charge of semiconductor wafer 10 may be reduced by grounding back coat 20 to a zero potential or a non-zero potential. In some embodiments of the invention, back coat 20 is grounded to a non-zero potential.

FIG. 7 shows a cross-sectional side view of another embodiment of the invention. Here, a layer of conductive material 21 is disposed beneath an oxide layer 16 within the bulk semiconductor 10. Functionally, the embodiment in FIG. 7 is similar to that in FIG. 4, with an induced charge 22 opposite in sign to accumulated charge 12 developing upon connecting conductive material 21 to ground 30.

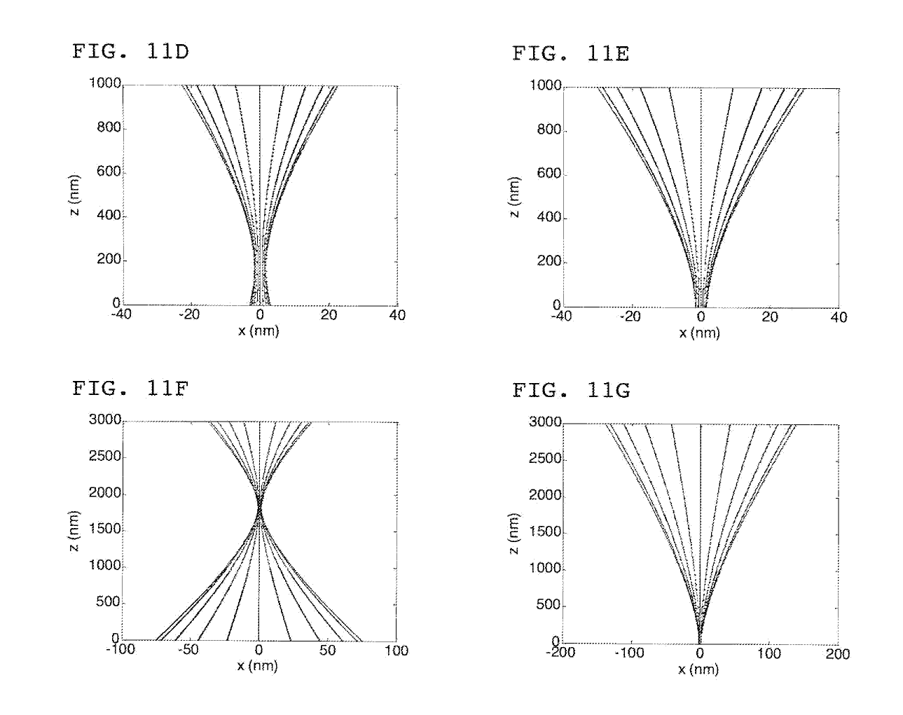

FIG. 8 shows a cross-sectional side view of yet another embodiment of the invention. Here, a thin, highly-conductive plate 23 capable of conformal attachment to semiconductor wafer 10 and connection to ground 30 may be alternately attached to and detached from semiconductor wafer 10. Such an embodiment may be particularly useful, for example, during loading and unloading semiconductor wafer 10 during processing and metrology. As in other embodiments of the invention, upon connecting plate 23 to ground 30, an induced charge will develop along plate 23 that is opposite in sign to an accumulated charge along or within semiconductor wafer 10.

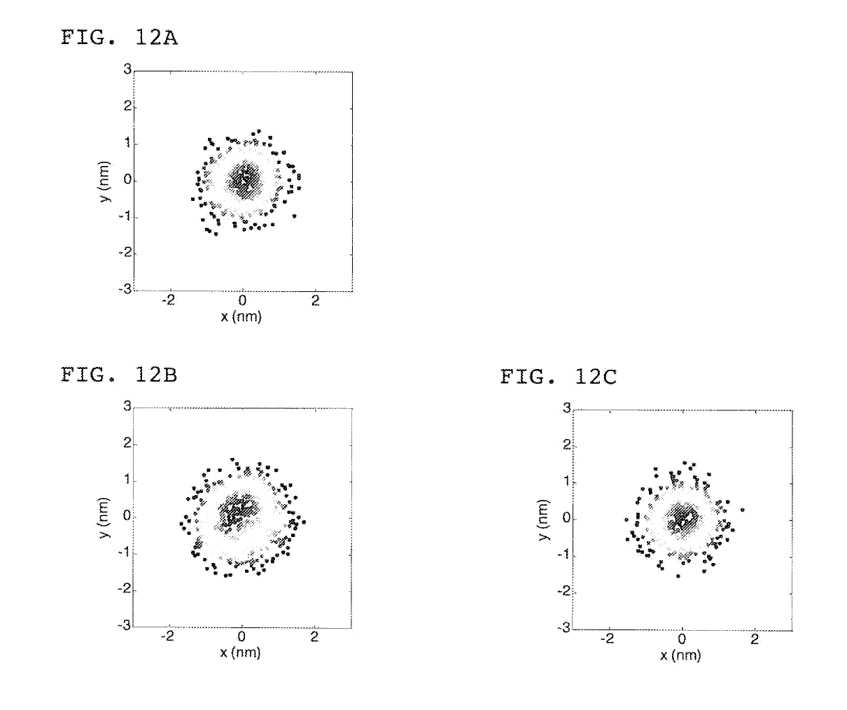

FIG. 9 shows a cross-sectional side view of still another embodiment of the invention. Here, a thin, conductive coating 24 of graphene and/or other conductive material(s) is applied to semiconductor wafer 10 prior to processing and/or metrology. Conductive coating 24 may be stripped from semiconductor wafer 10 after processing and/or metrology. Such an embodiment may be useful, for example, in cases where metal migration into semiconductor wafer 10 is to be avoided. Connecting conductive coating 24 to ground 30 will permit an induced charge to develop along conductive coating 24 that is opposite in sign to an accumulated charge along or within semiconductor wafer 10.

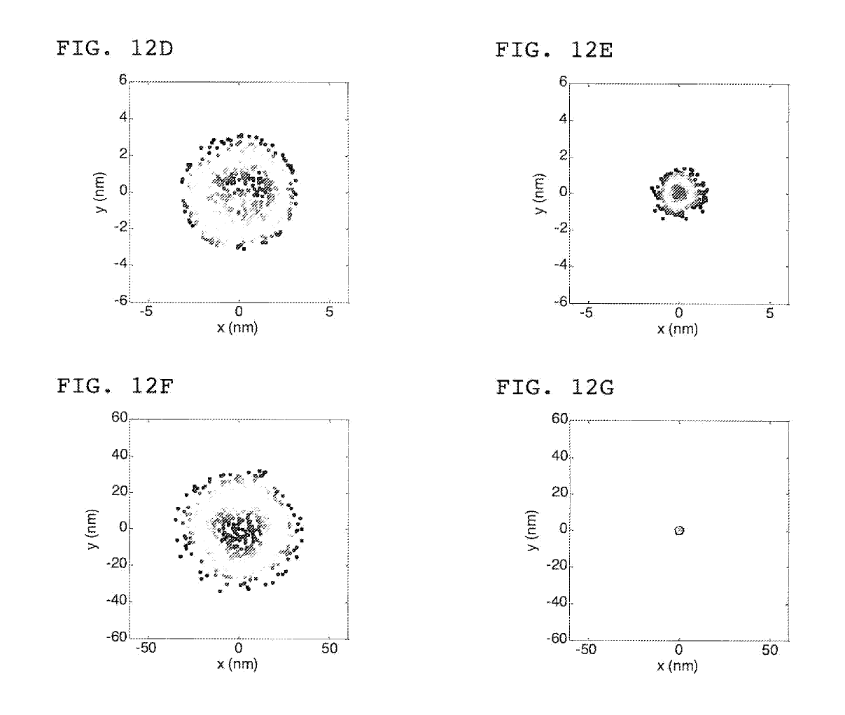

FIG. 10 shows a cross-sectional side view of yet another embodiment of the invention. Here, semiconductor wafer 10 includes a highly-doped layer 14 having increased conductivity. When connected to ground 30, an induced charge 22 develops along the highly-doped layer 14 that is opposite in sign to accumulated charge 12.

FIGS. 11A-G show numerical simulations of an impinging electron beam ray traces at various degrees of wafer charging, both with and without the back coat described above. FIG. 11A shows an electron beam ray trace of an uncharged (0 V) wafer. FIG. 11B shows an electron beam ray trace of a wafer with 10 V charging. Some distortion in the electron beam ray trace can be observed, as compared to FIG. 11A. FIG. 11C shows an electron beam ray trace of a wafer with 10 V charging and the grounded back coat described above. As can be seen in FIG. 11C, the electron beam ray trace is more similar to that in FIG. 11A than that in FIG. 11B.

FIGS. 11D-E and 11F-G show electron beam ray traces with greater wafer charging. FIG. 11D shows an electron beam ray trace with 50 V wafer charging. Significant distortion, including a rise in the focal point to approximately 200 nm, can be observed, as compared to the uncharged electron beam ray trace of FIG. 11A. FIG. 11E shows the electron beam ray trace with the same 50 V wafer charging, but with the grounded back coat described above. As can be seen, the electron beam ray trace of FIG. 11E is more similar to that of FIG. 11A and, specifically, the focal point is again returned to approximately the working surface.

FIG. 11F shows an electron beam ray trace with 300 V wafer charging. Very significant distortion can be seen, including a rise in the focal point to approximately 2000 nm. Distortion to this degree would render the wafer virtually unsuitable for processing or metrology. FIG. 11G shows the electron beam ray trace with the same 300 V wafer charging, but with the grounded back coat described above. In FIG. 11G, distortion is significantly reduced and the focal point returned to approximately the working surface. The difference in appearance of the electron beam ray traces of FIGS. 11G and 11A is primarily attributable a difference in the scale of FIG. 11G, which is made necessary for comparison to the electron beam ray trace of FIG. 11F.

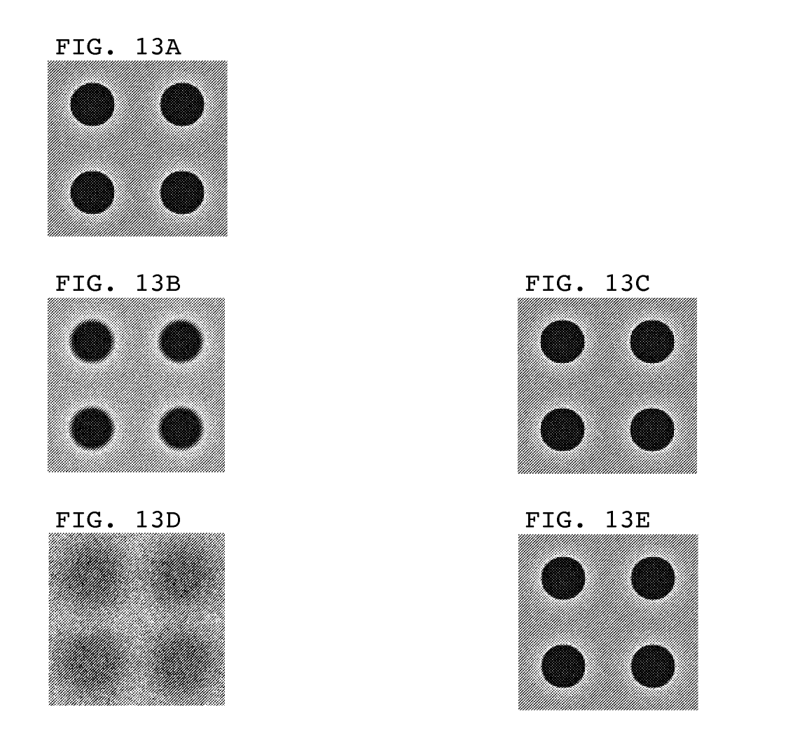

FIGS. 12A-G show the electron beam resolutions at the wafer surface corresponding to each of the electron beam ray traces of FIGS. 11A-G. FIG. 12A shows the electron beam resolution of the uncharged wafer. FIG. 12B shows the electron beam resolution of the 10 V wafer charging. A wider, more diffuse electron beam resolution is apparent in FIG. 12B, as compared to FIG. 12A. FIG. 12C shows the electron beam resolution of the 10 V wafer charging, but with the grounded back coat described above. The electron beam resolution of FIG. 12C is narrower and more compact than that of FIG. 12B and more closely resembles the electron beam resolution of the uncharged wafer in FIG. 12A.

FIGS. 12D and 12E show uncorrected and corrected electron beam resolutions, respectively, with 50 V wafer charging. Again, the electron beam resolution of FIG. 12E, where the grounded back coat described above was used, is narrower and more focused. The difference between the electron beam resolutions of FIGS. 12E and 12A is primarily attributable to a difference in scale.

The electron beam resolution of FIG. 12F, with 300 V wafer charging, is much broader and more diffuse than in FIG. 12A (again, taking into account the differences in scale). FIG. 12G shows the electron beam resolution with the same 300 V wafer charging, but with the grounded back coat described above. The electron beam resolution of FIG. 12G is narrower and more focused. The difference between the electron beam resolutions of FIGS. 12G and 12A is primarily attributable to a difference in scale.

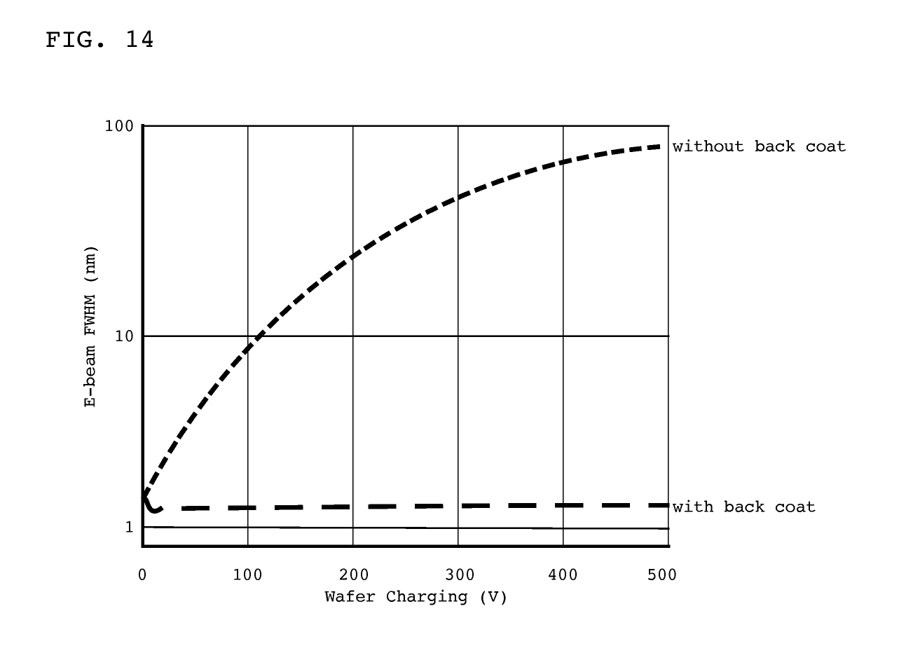

FIGS. 13A-E show CDSEM images at various wafer chargings. FIG. 13A shows a CDSEM image with no wafer charging (0 V). FIG. 13B shows the same CDSEM image with 50 V wafer charging. As can be seen in FIG. 13B, image focus is poorer and wafer features are less clear. FIG. 13C shows a CDSEM image with 50 V wafer charging and the grounded back coat described above. In FIG. 13C, image focus and feature clarity are substantially the same as in FIG. 13A and are improved as compared to FIG. 13B.

FIG. 13D shows a numerical simulation of a CDSEM image with 300 V wafer charging. Image focus and wafer features are so poor as to be largely unsuitable for processing or metrology. FIG. 13E shows a CDSEM image with the same 300 V wafer charging, but with the grounded back coat described above. As can be seen in FIG. 13E, image focus and feature clarity are substantially the same as in FIG. 13A and are greatly improved as compared to FIG. 13D.

FIG. 14 shows a graph of electron beam radius as a function of wafer charging, both with and without a ground back coat as described above. As can be seen in FIG. 14, with semiconductor wafers without a grounded back coat, electron beam radius consistently increases with increasing wafer charging. Contrarily, with semiconductor wafers with a grounded back coat, the electron beam radius is substantially constant as wafer charging increases.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A method of reducing an accumulated surface charge on a semiconductor wafer, the method comprising:
grounding a layer of conductive material adjacent a substrate of the wafer; and
allowing a mirrored charge substantially equal in magnitude and opposite in sign to the accumulated surface charge to be induced along the conductive material.

2. The method of claim 1, wherein grounding includes grounding to a non-zero potential.

3. The method of claim 1, wherein the layer of conductive material is selected from a group consisting of: a back coat of conductive material along a surface of the substrate, a layer of conductive material disposed along an oxide layer within the substrate, a layer of graphene along a surface of the substrate, and a plate suitable for non-fixed attachment to the substrate.

4. The method of claim 1, wherein the induced mirrored charge reduces a total potential of the semiconductor by approximately an order of magnitude.

5. The method of claim 1, wherein the conductive material includes at least one material selected from a group consisting of: copper, silver, aluminum, gold, tungsten, zinc, nickel, lithium, iron, platinum, tin, lead, titanium, graphite, carbon nanotubes, and carbon nanowires.

6. The method of claim 1, wherein an electric potential caused by the mirrored charge is calculated according to Equation 1,
$$I = - \frac{σ}{2 ɛ ( \sqrt{{( z + 2 d )}^{2} + {D}^{2}} - z - 2 d )} , \qquad Equation 1$$
wherein z is a distance from a surface of the semiconductor wafer, d is a thickness of the semiconductor wafer, D is a diameter of the semiconductor wafer, σ is a surface charge density and ∈ is a permittivity constant.

7. The method of claim 6, wherein an electric potential caused by the accumulated surface charge is calculated according to Equation 2,
$$A = \frac{σ}{2 ɛ ( \sqrt{{z}^{2} + {D}^{2}} - z )} , \qquad Equation 2$$
wherein ∈ is a permittivity constant.

8. The method of claim 7, wherein a total potential of the semiconductor wafer is calculated according to Equation 3,
$${V}_{total} = ( \frac{σ}{2 ɛ} \sqrt{{z}^{2} + {D}^{2}} - z ) \frac{σ}{2 ɛ [ ( \sqrt{{z}^{2} + {D}^{2}} - z ) - ( \sqrt{{( z + 2 d )}^{2} + {D}^{2}} - z - 2 d ) ]} . \qquad Equation 3$$

9. A method of reducing an accumulated bulk charge in a semiconductor wafer, the method comprising:
grounding a layer of conductive material adjacent a substrate of the wafer; and
allowing a mirrored charge substantially equal in magnitude and opposite in sign to the accumulated bulk charge to be induced along the conductive material.

10. The method of claim 9, wherein grounding includes grounding to a non-zero potential.

11. The method of claim 9, wherein the layer of conductive material is selected from a group consisting of: a back coat of conductive material along a surface of the substrate, a layer of conductive material disposed along an oxide layer within the substrate, a layer of graphene along a surface of the substrate, and a plate suitable for non-fixed attachment to the substrate.

12. The method of claim 9, wherein the conductive material includes at least one material selected from a group consisting of: copper, silver, aluminum, gold, tungsten, zinc, nickel, lithium, iron, platinum, tin, lead, titanium, graphite, carbon nanotubes, and carbon nanowires.

13. The method of claim 9, wherein an electric potential caused by the mirrored charge is calculated according to Equation 1,
$$I = - \frac{σ}{2 ɛ ( \sqrt{{( z + 2 d )}^{2} + {D}^{2}} - z - 2 d )} , \qquad Equation 1$$
wherein z is a distance from a surface of the semiconductor wafer, d is a thickness of the semiconductor wafer, D is a diameter of the semiconductor wafer, σ is a surface charge density and ∈ is a permittivity constant;
an electric potential caused by the accumulated bulk charge is calculated according to Equation 2,
$$A = \frac{σ}{2 ɛ ( \sqrt{{z}^{2} + {D}^{2}} - z )} , \qquad Equation 2$$
wherein ∈ is a permittivity constant; and
a total potential of the semiconductor wafer is calculated according to Equation 3,
$${V}_{total} = ( \frac{σ}{2 ɛ} \sqrt{{z}^{2} + {D}^{2}} - z ) \frac{σ}{2 ɛ [ ( \sqrt{{z}^{2} + {D}^{2}} - z ) - ( \sqrt{{( z + 2 d )}^{2} + {D}^{2}} - z - 2 d ) ]} . \qquad Equation 3$$
